(19) United States
(12) Patent Application Publication
(10) Pub. No.: US 2011/0291167 A1
(43) Pub. Date: Dec. 1, 2011

(54) SEMICONDUCTOR DEVICE

(75) Inventors: Yoshiaki Shimooka, Tokyo (JP); Hiroaki Yamazaki, Yokohama-shi (JP)

(73) Assignee: KABUSHIKI KAISHA TOSHIBA, Tokyo (JP)

(21) Appl. No.: 13/048,048

(22) Filed: Mar. 15, 2011

(30) Foreign Application Priority Data
May 28, 2010 (JP) 2010-122736

(51) Int. Cl. H01L 29/78

(52) U.S. Cl. 257/296; 257/E29.255

(57) ABSTRACT

In one embodiment, a semiconductor device includes a substrate having a through hole, and a MEMS capacitor provided above the substrate. The device further includes an integrated circuit configured to control the MEMS capacitor, the circuit including transistors on the substrate and being provided under the MEMS capacitor and on the substrate. Further, an area on the substrate immediately under the MEMS capacitor overlaps at least partially with the through hole.

### CROSS REFERENCE TO RELATED APPLICATION

This application is based upon and claims the benefit of priority from the prior Japanese Patent Application No. 2010-122736, filed on May 28, 2010, the entire contents of which are incorporated herein by reference.

### FIELD

Embodiments described herein relate to a semiconductor device.

### BACKGROUND

As a conventional semiconductor device, there is known a semiconductor device that includes a MEMS (Micro Electro Mechanical System) capacitor on a semiconductor substrate via an insulating film in order to reduce a parasitic capacitance that occurs between the MEMS capacitor and the semiconductor substrate. According to such a semiconductor device, the capacitance can be reduced greatly as the thickness of the insulating film becomes thicker. However, when the thickness of the insulating film becomes thicker, the difference in stress between the insulating film and the semiconductor substrate becomes larger. This may cause warpage of the semiconductor substrate.

Further, as a conventional semiconductor device, there is known a semiconductor device having a structure in which the MEMS capacitor and a control integrated circuit for the capacitor are formed on the same substrate. In such a semiconductor device, when the MEMS capacitor and the control integrated circuit are vertically arranged, their footprints can be reduced.

However, in a case where a first insulating film for reducing the parasitic capacitance and a second insulating film including the control integrated circuit are formed between the MEMS capacitor and the semiconductor substrate, there is a problem that the warpage caused in the semiconductor substrate becomes larger than in a case where only the first insulating film is formed. If the warpage is caused in the semiconductor substrate, it causes a problem that desired process steps become difficult to perform in the manufacturing process, and a problem that a transfer trouble is caused inside the manufacturing tools.

Further, as another semiconductor device, there is known a semiconductor device in which an electronic device such as a MEMS device is formed on the substrate, and a conductive via plug formed in a partially thinned area on the substrate is electrically connected with the electronic device.

Moreover, as another semiconductor device, there is known a semiconductor device in which an inductor is formed on the substrate, and a through hole is formed in an area on the substrate under the inductor.

### BRIEF DESCRIPTION OF THE DRAWINGS

FIG. 1 is a vertical sectional view of a semiconductor device according to a first embodiment;

FIG. 2 is a plan view schematically showing a positional relation between a MEMS capacitor and a through hole area in a horizontal direction in the first embodiment;

FIGS. 3A to 5B are vertical sectional views showing a manufacturing process of the semiconductor device according to the first embodiment;

FIG. 6 is a vertical sectional view of a semiconductor device according to a second embodiment; and

FIGS. 7A and 7B are plan views each schematically showing a pattern of through holes in a through hole area on a semiconductor substrate in a third embodiment.

### DETAILED DESCRIPTION

Embodiments will now be explained with reference to the accompanying drawings.

An embodiment described herein is a semiconductor device including a substrate having a through hole, and a MEMS capacitor provided above the substrate. The device further includes an integrated circuit configured to control the MEMS capacitor, the circuit including a transistor on the substrate and being provided under the MEMS capacitor and on the substrate. Further, an area on the substrate immediately under the MEMS capacitor overlaps at least partially with the through hole.

### First Embodiment

### Configuration of Semiconductor Device

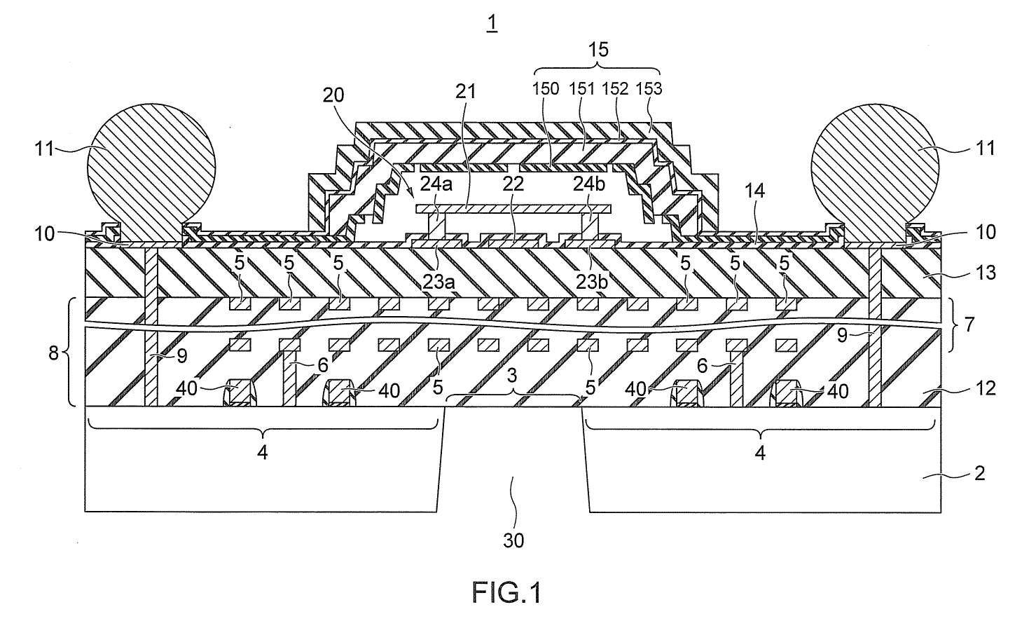

FIG. 1 is a vertical sectional view of a semiconductor device 1 according to a first embodiment.

The semiconductor device 1 includes a semiconductor substrate 2, an insulating layer 12 formed on the semiconductor substrate 2, a control integrated circuit 8 formed in the insulating layer 12, an insulating layer 13 formed on the insulating layer 12, an insulating film 14 that covers the surface of the insulating layer 13, a MEMS capacitor 20 formed on the insulating layer 13, and an encapsulation 15 that covers the MEMS capacitor 20.

The semiconductor substrate 2 has a through hole area 3 which includes a through hole 30.

The control integrated circuit 8 includes transistors 40 formed on the semiconductor substrate 2, and the multilayer interconnects 7 including interconnects 5 electrically connected to the transistors 40 through contact plugs 6. The control integrated circuit 8 is used for controlling an electric capacitance of the MEMS capacitor 20 and the like. The control integrated circuit 8 is an example of an integrated circuit of the disclosure. Some of the interconnects 5 are formed immediately under the MEMS capacitor 20 and immediately above the through hole 30. In FIG. 1, interconnects 5 included in plural layer levels in the control integrated circuit 8 are formed immediately under the MEMS capacitor 20 and immediately above the through hole 30.

The transistors 40 are formed on a transistor formation area 4 on the semiconductor substrate 2. For arranging the transistors 40 efficiently, the transistor formation area 4 on the semiconductor substrate 2 is preferably arranged so as to surround the through hole area 3.

Solder bumps 11 are electrically connected to the transistors 40 through contact plugs 9 and electrode pads 10, and have functions as electrodes for electrically connecting external devices to the control integrated circuit 8.

The MEMS capacitor 20 has a signal line 22 as a lower electrode, ground lines 23a and 23b electrically connected to GND, anchor parts 24a and 24b formed respectively on the ground lines 23a and 23b, and a bridge 21 as an upper electrode formed across the anchor parts 24a, 24b.

When a voltage is applied between the bridge 21 and the signal line 22, it causes transformation of the bridge 21, leading to a change in space between the bridge 21 and the signal line 22. This causes a change in electric capacitance. A MEMS capacitor having a different structure from the above MEMS capacitor 20 may also be used.

The insulating layer 13 is, for example, formed of an insulator with a thickness of 10 μm or more, and has a function of reducing a parasitic capacitance that occurs between the semiconductor substrate 2 and the MEMS capacitor 20. Although the parasitic capacitance becomes smaller with increase in thickness of the insulating layer 13, the semiconductor substrate 2 becomes apt to be warped.

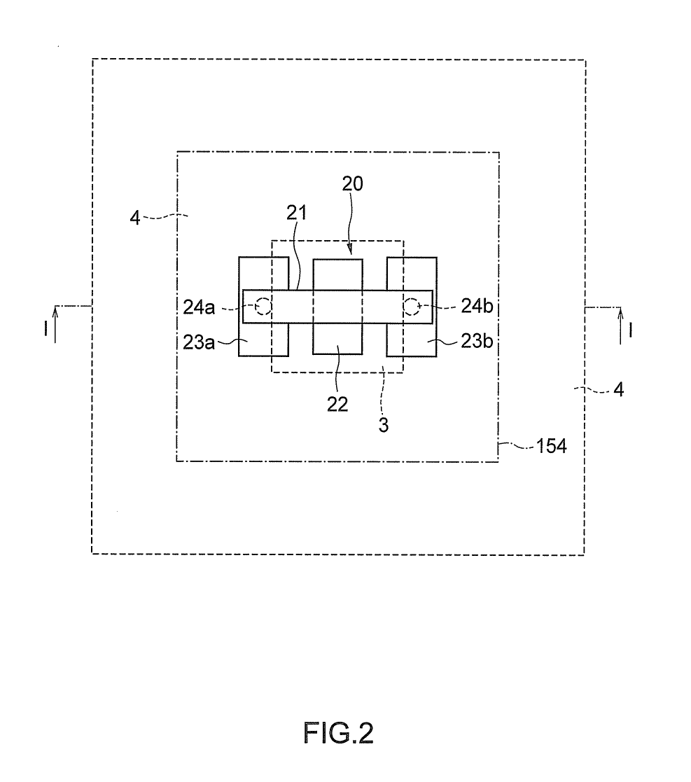

FIG. 2 is a plan view schematically showing a positional relation between the MEMS capacitor 20 and the through hole area 3 of the semiconductor substrate 2 in a horizontal direction (i.e., in a parallel direction to the surface of the semiconductor substrate 2). Further, FIG. 2 shows an inner outline 154 of the bottom of the encapsulation 15. A cross section of the semiconductor device 1 along a line I-I of FIG. 2 corresponds to the cross section of FIG. 1.

As shown in FIG. 2, an area on the semiconductor substrate 2 immediately under the MEMS capacitor 20 overlaps at least partially with the through hole area 3. In other words, the semiconductor substrate 2 does not exist in at least a part of the area immediately under the MEMS capacitor 20. Therefore, the parasitic capacitance that occurs between the MEMS capacitor 20 and the semiconductor substrate 2 is reduced by forming the through hole area 3.

In FIG. 2, the area on the semiconductor substrate 2 immediately under the signal line 22 is surrounded by the through hole area 3. Further, areas on the semiconductor substrate 2 which are immediately under the ground lines 23a and 23b overlap at least partially with the through hole area 3.

As an indicator of the characteristics of a capacitor, a parameter called value Q is used. The value Q is expressed by a formula Q=1/(ωCR). As the value Q is larger, it indicates better capacitor characteristics. Herein, ω represents an angular frequency of an electric signal flowing along the signal line, C represents a total of a variable capacitance value inside the MEMS capacitor and the parasitic capacitance between the MEMS capacitor and the semiconductor substrate, and R represents electric resistance of the signal line.

Reduction in parasitic capacitance between the MEMS capacitor and the semiconductor substrate can decrease C without reducing the variable capacitance value inside the MEMS capacitor. This can increase the Q value.

The parasitic capacitance caused between the MEMS capacitor 20 and the semiconductor substrate 2 can be greatly reduced as an area in which the through hole area 3 is formed (i.e., the through hole 30 is formed) becomes large. However, if the area in which the through hole area 3 is formed becomes excessively large, it may cause deterioration in mechanical strength of the semiconductor substrate 2 and reduction in transistor formation area 4. Therefore, the through hole area 3 preferably has a size to such a degree as to be surrounded by an area on the semiconductor substrate 2 immediately under the encapsulation 15.

The semiconductor substrate 2 is, for example, formed of Si-based crystal such as Si crystal.

The insulating layer 12 is formed of insulating material such as SiO₂.

The encapsulation 15 is a cap for protecting the MEMS capacitor 20. The encapsulation 15 is a thin film dorm having a structure including stacked insulating thin films 150, 151, 152, and 153. The thin film 150 has a plurality of through holes. The thin film 151 has a higher gas transmittance than the thin film 150, and the thin film 152 has a lower transmittance than the thin film 151. The thin film 153 has a higher elasticity than the thin film 152. The thin films 150, 151, 152, and 153 are examples of first, second, third, and fourth films of the disclosure, respectively. In addition, a cap other than the thin film dorm, such as an Si cap formed of polycrystalline Si, may also be used as the encapsulation 15.

Each of the transistors 40 includes a gate insulator on the semiconductor substrate 2, a gate electrode on the gate insulator, a gate side walls on the side faces of the gate electrode, and source and drain regions (not shown) on both sides of the gate electrode. The gate insulator, the gate electrode, and the gate side walls are formed of SiO₂, polycrystalline Si, and SiO₂, respectively.

The interconnects 5 are formed of conductive material such as Cu, Al or the like.

The contact plugs 6 and 9 are formed of conductive material such as W, Cu or the like.

The solder bumps 11 are formed of solder member such as Sn, SnAg, SnAgCu, or PbSn. Further, a barrier metal formed of Ni, Ti, TIN or the like may be formed on the bottom of each solder bump 11.

The insulating layer 13 is formed of insulating material such as SiO₂ or SiN. Further, a coating-type organic film may also be used as the insulating layer 13.

The insulating film 10 is formed of insulating material such as SiO₂.

The bridge 21, the signal line 22, the ground lines 23a and 23b, and the anchor parts 24a and 24b are, for example, formed of metal material such as Al, Ni or the like.

Hereinafter, an example of a method of manufacturing the semiconductor device 1 according to the first embodiment is shown.

### (Manufacture of Semiconductor Device)

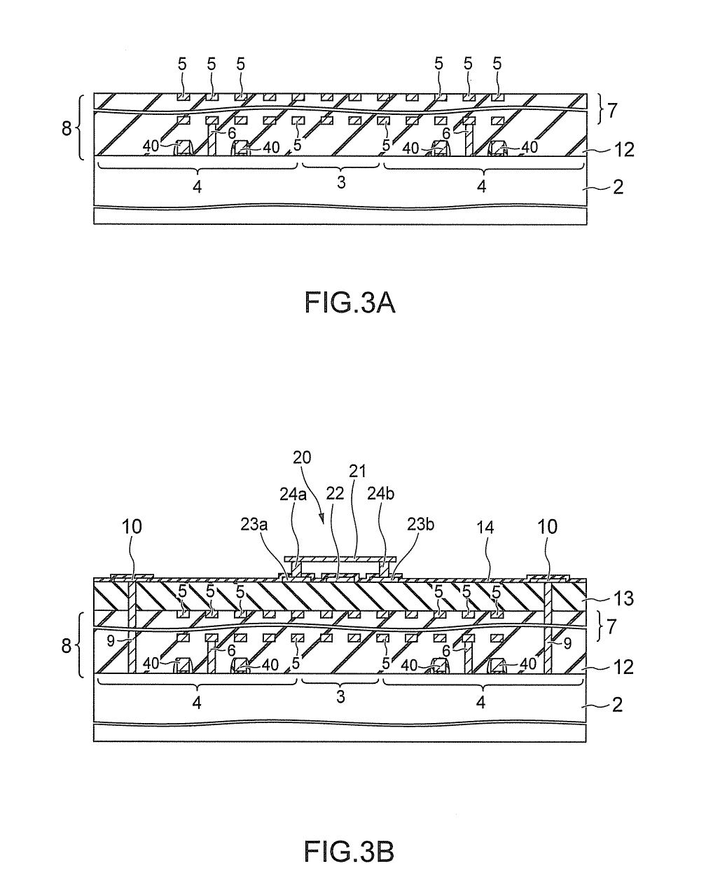

FIGS. 3A to 5B are vertical sectional views showing a manufacturing process of the semiconductor device 1 according to the first embodiment.

First, as shown in FIG. 3A, the control integrated circuit 8 in the insulating layer 12 is formed on the semiconductor substrate 2 by a known method. At this time, the transistors 40 are formed on the transistor formation area 4, but not formed on the through hole area 3.

Then, as shown in FIG. 3B, the insulating layer 13, the insulating layer 14 and the MEMS capacitor 20 are formed.

The insulating layer 13 is formed by depositing insulating material on the insulating layer 12 by CVD (Chemical Vapor Deposition) or the like.

The signal line 22 and the ground lines 23a and 23b are formed by patterning a metal film formed on the insulating layer 13. The insulating layer 14 is formed on the signal line 22 and the ground lines 23a and 23b by CVD or the like.

The anchor parts 24a and 24b and the bridge 21 are formed respectively on the side faces and the top face of a sacrifice layer (not shown) which is formed on the insulating layer 14. The sacrifice layer is removed after the anchor parts 24a and 24b and the bridge 21 are formed.

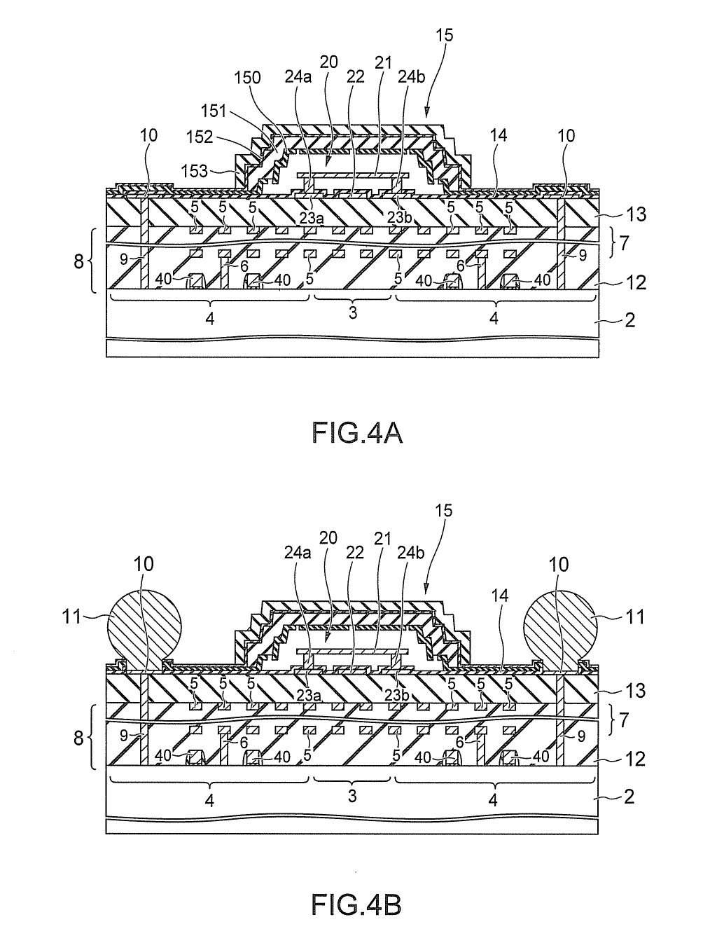

Then, as shown in FIG. 4A, the encapsulation 15 formed of the thin films 150, 151, 152, and 153 is formed. The thin film 150 is formed on the sacrifice layer (not shown) so as to cover the MEMS capacitor 20. After the thin film 150 is formed, the sacrifice layer is removed via the through holes of the thin film 150. The thin films 151, 152, and 153 are stacked on the thin film 150.

Then, as shown in FIG. 4B, the solder bumps 11 are formed. For example, the solder bumps 11 are formed by the following method. First, a resist film having apertures is formed on a seed layer formed by plating or sputtering. Then, a barrier metal and a solder layer are formed in the apertures of the resist film by plating. Thereafter, the resist film and the seed film are removed. The solder layer is formed into spherical shapes by thermal treatment.

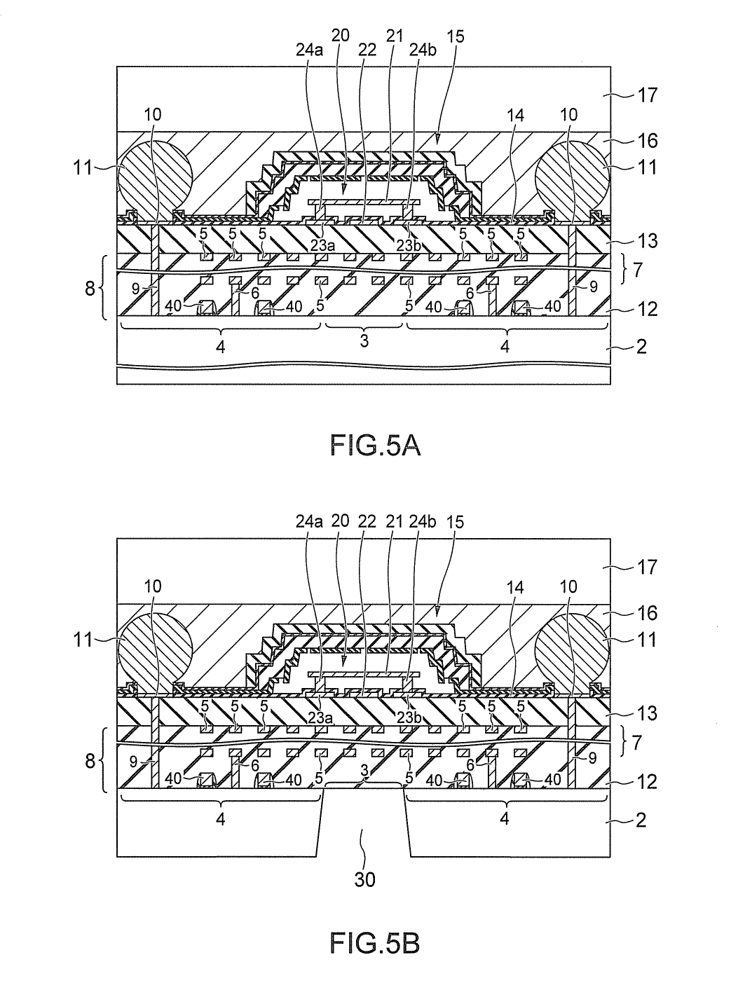

Then, as shown in FIG. 5A, an adhesive layer 16 formed of a thermosetting resin or the like is formed all over the semiconductor substrate 2, and the support substrate 17 is adhered onto the adhesive layer 16.

Then, as shown in FIG. 5B, the semiconductor substrate 2 is made thinner by polishing, and the through hole 30 is then formed in the through hole area 3. The polishing makes the semiconductor substrate 2 to have a thickness of 100 to 300 μm, for example.

After a resist mask having a pattern of the through hole 30 is formed on the back side of the semiconductor substrate 2 (the lower-side face in FIG. 5B) by photolithography, the semiconductor substrate 2 is etched, thereby forming the through hole 30. The etching is performed by RIE (Reactive Ion Etching), wet etching with a TMAH (Tetra Methyl Ammonium Hydroxide) solution, wet etching with a KOH (calcium hydrate) solution or the like.

After the through hole 30 is formed, the adhesive layer 16 and the support substrate 17 are separated by thermal treatment, UV irradiation or the like.

### Second Embodiment

A second embodiment is different from the first embodiment in that an insulating layer is formed on the back side of the semiconductor substrate 2 so as to be buried in the through hole 30.

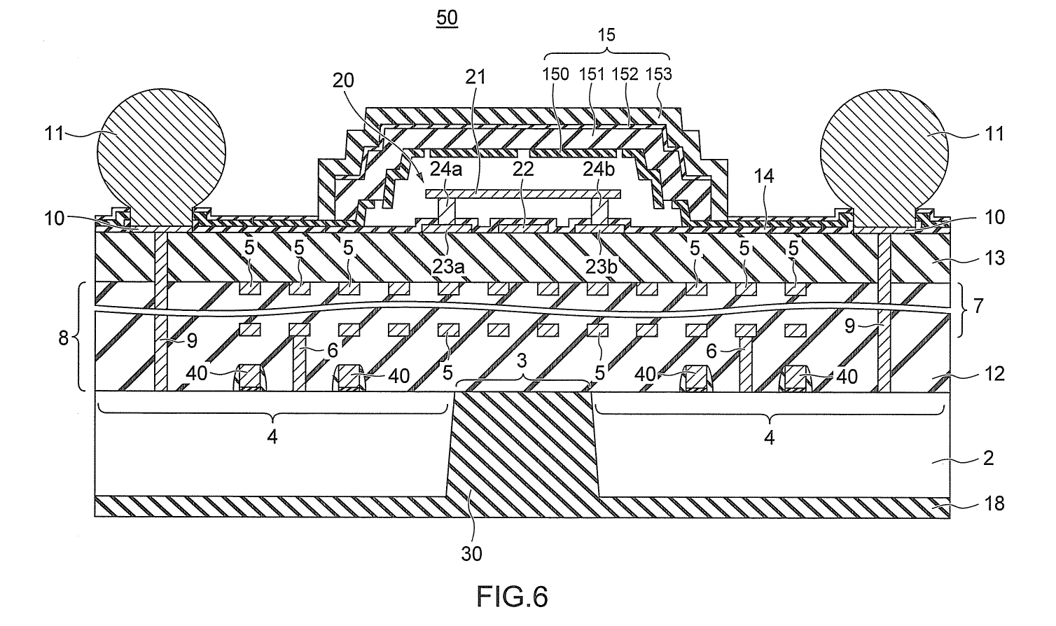

FIG. 6 is a vertical sectional view of a semiconductor device 50 according to the second embodiment. The semiconductor device 50 has a buried layer 18 formed on the back side of the semiconductor substrate 2 so as to be buried in the through hole 30. The other structures are similar to those of the semiconductor device 1 of the first embodiment.

The buried layer 18 is, for example, formed of an insulator such as an SOG (Spin-On Glass) film or the like, and has a function of suppressing deterioration in mechanical strength of the semiconductor substrate 2 due to the formation of the through hole 30. The buried layer 18 has such a shape as to fill in at least the through hole 30. In FIG. 6, the buried layer 18 is formed continuously in the through hole 30 and on the back side of the semiconductor substrate 2.

After the process steps until the through hole 30 is formed are performed in a similar manner to the first embodiment, the buried layer 18 is formed. After the buried layer 18 is formed, the adhesive layer 16 and the support substrate 17 are separated.

### Third Embodiment

A third embodiment is different from the first embodiment in a pattern of through holes in the through hole area 3.

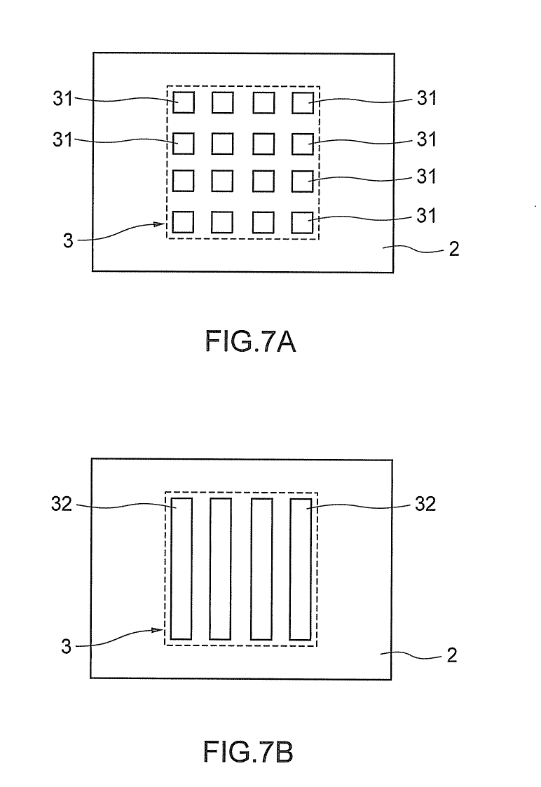

FIGS. 7A and 7B are plan views each schematically showing a pattern of through holes in the through hole area 3 on the semiconductor substrate 2.

FIG. 7A shows a plurality of through holes 31 formed such that the semiconductor substrate 2 has a lattice pattern in the through hole area 3. In this lattice pattern, the plurality of through holes 31 having square or rectangular planar shapes are arranged in lattice shape. FIG. 7B shows a plurality of through holes 32 formed such that the semiconductor substrate 2 has a line-and-space pattern in the through hole area 3. In this line-and-space pattern, the plurality of through holes 32 having stripe planar shapes are arranged in parallel with one another. Deterioration in mechanical strength of the semiconductor substrate 2 due to the formation of the through holes can be suppressed by forming such patterns including the plurality of through holes.

The pattern of the through holes in the through hole area 3 shown in each of FIGS. 7A and 7B is an example. Therefore, the shape, number, arrangement and the like of the through holes in the through hole area 3 are not limited. However, in any case, the area on the semiconductor substrate 2 immediately under the MEMS capacitor 20 overlaps at least partially with the through hole area 3, as in the first embodiment.

Further, the third embodiment may be combined with the second embodiment. In this case, the buried layer 18 is formed so as to be buried in the through holes 31 or 32 or other through holes.

According to the first to third embodiments, the parasitic capacitance that occurs between the MEMS capacitor 20 and the semiconductor substrate 2 can be reduced by forming the through hole area 3 including the through hole 30 on the semiconductor substrate 2. Therefore, the thickness of the insulating layer 13 is allowed to be made small for reducing the parasitic capacitance. Therefore, even in the case of forming the control integrated circuit 8 in a layer under the MEMS capacitor 20, it is possible to suppress the warpage that occurs in the semiconductor substrate 2.

Further, in the case where the interconnects 5 in the multilayer interconnects 7 are formed immediately under the MEMS capacitor 20, a parasitic capacitance also occurs between the MEMS capacitor 20 and the interconnects 5. However, since the parasitic capacitance that occurs between the MEMS capacitor 20 and the semiconductor substrate 2 is small, the total parasitic capacitance can be held small even in the above case. Therefore, the freedom in the layout design of the interconnects 5 is improved by forming the through hole area 3. However, when the parasitic capacitance is wanted to be reduced to a greater degree, the interconnects 5 are preferably not formed immediately under the MEMS capacitor 20.

When the parasitic capacitance can be sufficiently suppressed even without the insulating layer 13 by forming the through hole area 3 on the semiconductor substrate 2, the insulating layer 13 as a film for suppressing the parasitic capacitance may not be formed. However in that case, it is necessary to provide another insulating layer for insulating the interconnects 5 on the uppermost layer of the multilayer interconnects 7 from the signal line 22 and the ground lines 23a and 23b of the MEMS capacitor 20.

The sequence of the manufacturing process for the semiconductor device is not limited to those shown in the above embodiments.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

1. A semiconductor device comprising:
a substrate having a through hole;
a MEMS capacitor provided above the substrate; and
an integrated circuit configured to control the MEMS capacitor, the circuit including a transistor on the substrate and being provided under the MEMS capacitor and on the substrate,
wherein an area on the substrate immediately under the MEMS capacitor overlaps at least partially with the through hole.

2. The device of claim 1, wherein
at least an interconnect in the integrated circuit is provided immediately under the MEMS capacitor and immediately above the through hole.

3. The device of claim 1, further comprising:
an insulating layer provided between the MEMS capacitor and the integrated circuit, and having a function of reducing a parasitic capacitance between the MEMS capacitor and the substrate.

4. The device of claim 3, wherein the insulating layer is a silicon oxide film, a silicon nitride film, or a coating-type organic film.

5. The device of claim 3, wherein a thickness of the insulating layer is equal to or smaller than 10 μm.

6. The device of claim 1, wherein a thickness of the substrate is 100 to 300 μm.

7. The device of claim 1, wherein an area on the substrate on which the transistor is provided surrounds the through hole.

8. The device of claim 1, further comprising an insulating layer which is buried in the through hole.

9. The device of claim 8, wherein the buried layer is continuously provided in the through hole and on a back side of the semiconductor substrate.

10. The device of claim 1, wherein the through hole includes a plurality of through holes.

11. The device of claim 10, wherein the plurality of through holes are provided to have a lattice pattern.

12. The device of claim 10, wherein the plurality of through holes are provided to have a line and space pattern.

13. The device of claim 1, further comprising an encapsulation provided on the substrate to cover the MEMS capacitor,
wherein an area on the substrate immediately under the encapsulation overlaps at least partially with the through hole.

14. The device of claim 13, wherein the encapsulation has a dorm structure covering the MEMS capacitor.

15. The device of claim 13, wherein the encapsulation includes stacked films.

16. The device of claim 15, wherein the stacked films comprises:
a first film including a plurality of through holes;
a second film provided on the first film and having a higher gas transmittance than the first film; and
a third film provided on the second film and having a lower gas transmittance than the second film.

17. The device of claim 16, wherein the stacked films further comprises:
a fourth film provided on the third film and having a higher elasticity than the third film.

18. The device of claim 1, wherein
a plurality of interconnects are provide in the integrated circuit,
the plurality of interconnects are provided immediately under the MEMS capacitor and immediately above the through hole, and
the plurality of interconnects are provided in a plurality of layer levels of the integrated circuit.

19. The device of claim 1, wherein the MEMS capacitor comprises:
a signal line provided above the substrate;
ground lines provided above the substrate;
anchor parts provided on the respective ground lines; and
a bridge provided across the anchor parts.

20. The device of claim 19, wherein
an area on the substrate immediately under the signal line is surrounded by the through hole area, and
areas on the substrate immediately under the ground lines overlap at least partially with the through hole area.
